(19) United States
(12) Patent Application Publication
(10) Pub. No.: US 2016/0071954 A1
(43) Pub. Date: Mar. 10, 2016

(54) ROBUST POST-GATE SPACER PROCESSING AND DEVICE

(71) Applicant: GLOBALFOUNDRIES Inc., Grand Cayman (KY)

(72) Inventors: Jan HOENTSCHEL, Dresden (DE); Sven BEYER, Dresden (DE); Ralf ILLGEN, Dresden (DE); Alexander EBERMANN, Dresden (DE)

(21) Appl. No.: 14/476,885

(22) Filed: Sep. 4, 2014

(51) Int. Cl. H01L 29/66; H01L 21/265; H01L 21/28; H01L 21/285; H01L 21/311; H01L 21/02

(52) U.S. Cl. CPC H01L 29/66568; H01L 21/31116; H01L 21/02164; H01L 21/0217; H01L 21/28088; H01L 21/28518; H01L 29/665; H01L 21/26513

(57) ABSTRACT

A methodology for robust post-gate spacer processing that exhibits reduced variability and marginalities, and the resulting device are disclosed. Embodiments may include forming an oxide layer over a gate stack, forming a nitride layer over the oxide layer, partially removing the nitride layer to expose a portion of the oxide layer, forming a protective nitride layer directly over the partially exposed oxide layer and a remaining portion of the nitride layer, removing the protective nitride layer from the gate stack, and at least partially removing the remaining portion of the nitride layer.

### TECHNICAL FIELD

The present disclosure relates to the fabrication of semiconductor devices having variable gate lengths. The present disclosure particularly relates to post-gate, pre-silicidation spacer processing at gate pitch values for the 32 nanometer (nm) technology node and beyond.

### BACKGROUND

Modern integrated circuits (ICs) utilize several different polysilicon (“poly”) pitch values depending on a desired gate length for a particular device on the IC. However, continuously scaled pitch values minimize the space available for implants, stress memorization techniques, silicidation, dual stress liners, and contacts. As dimensions shrink, the process margin in each individual process step and tolerance for process variability decreases.

Also, after spacers are formed, a silicide block mask, or resistor protection layer, is required to protect the poly and diffusion resistors from silicide formation. To protect the underlying layers when the resistor protection layer is removed (from places in which a silicide is to be formed), an oxide etch stop layer is formed under the protection layer. The etch stop layer must then be removed to expose the silicon source and drain regions for silicidation. In addition, a spacer pull back process (i.e., partial removal of the outermost spacers) is required prior to contact integration to increase the space for the source and drain contacts. However, the spacer etch erodes the silicide, which increases contact resistance, which in turn degrades device performance.

A need therefore exists for methodology enabling a more robust and cost-efficient post-gate spacer processing while allowing cost-efficient gate pitch scaling.

### SUMMARY

An aspect of the present disclosure is skipping an oxide liner deposition under a silicide block mask and removal thereof during post-gate processing.

Another aspect of the present disclosure is depositing a nitride resistor protection layer directly over a partially exposed oxide layer and combining a spacer pull back process with etching of the resistor protection layer prior to silicidation.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming an oxide layer over a gate stack, forming a nitride layer over the oxide layer, partially removing the nitride layer to expose a portion of the oxide layer, forming a protective nitride layer directly over the partially exposed oxide layer and a remaining portion of the nitride layer, and removing the protective nitride layer from the gate stack and at least partially removing the remaining portion of the nitride layer.

Aspects of the present disclosure include the gate stack including a gate electrode, a nitride formed on sidewalls of the gate electrode, and oxide formed on the nitride. Further aspects include partially removing the nitride layer by reactive ion etching (RIE) horizontal surfaces of the nitride layer. Additional aspects include partially removing the nitride layer to expose the oxide layer at a top surface of the gate stack. Further aspects include partially removing the remaining portion of the nitride layer to expose the oxide layer at top and upper sidewall surfaces of the gate stack. Additional aspects include removing exposed portions of the oxide layer to expose top and upper sidewall surfaces of a gate electrode, and forming a gate silicide at exposed portions of the gate electrode. Further aspects include forming the nitride layer directly on the oxide layer. Additional aspects include the gate stack including a high-K metal gate (HKMG). Further aspects include forming the protective nitride layer to a thickness of 100 to 300 angstroms (Å).

Another aspect of the present disclosure is a method including forming an oxide layer over a gate stack, forming a nitride layer over the oxide layer, partially removing the nitride layer to expose a portion of the oxide layer, forming a protective nitride layer directly over the partially exposed oxide layer and a remaining portion of the nitride layer, and removing the protective nitride layer from the gate stack and at least partially removing the remaining portion of the nitride layer, the partial removal of the nitride layer exposing the oxide layer at a top surface of the gate stack, and at least partially removing the remaining portion of the nitride layer to expose the oxide layer at top and upper sidewall surfaces of the gate stack. Additional aspects include the gate stack including a gate electrode, a nitride formed on sidewalls of the gate electrode, and oxide formed on the nitride. Further aspects include partially removing the nitride layer by RIE horizontal surfaces of the nitride layer. Additional aspects include removing exposed portions of the oxide layer to expose top and upper sidewall surfaces of a gate electrode and forming a gate silicide at exposed portions of the gate electrode. Further aspects include forming the nitride layer directly on the oxide layer. Additional aspects include the gate stack including a HKMG. Further aspects include forming the protective nitride layer to a thickness of 100 to 300 Å.

Aspects include a method comprising: forming an oxide layer over a gate stack, a source region, and drain region, forming a nitride layer over the oxide layer, partially removing the nitride layer to expose a portion of the oxide layer at a top surface of the gate stack and the source and drain regions, performing a deep implantation at the source and drain regions, forming a protective nitride layer directly over the exposed portion of the oxide layer, the source and drain regions, and a remaining portion of the nitride layer, removing the protective nitride layer from the gate stack and the source and drain regions, and at least partially removing the remaining portion of the nitride layer, to expose a portion of the oxide layer at top and upper sidewall surfaces of the gate stack and over the source and drain regions, removing the exposed portions of the oxide layer to expose top and upper sidewall surfaces of a gate electrode and the source and drain regions, and forming a silicide on the gate electrode and the source and drain regions. Additional aspects include the gate stack including a HKMG, a nitride formed on sidewalls of the HKMG, and oxide formed on the nitride. Further aspects include forming the nitride layer directly on the oxide layer and partially removing the nitride layer by RIE horizontal surfaces of the nitride layer. Additional aspects include forming the protective nitride layer to a thickness of 100 to 300 Å.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1G schematically illustrate a conventional post-gate spacer process; and

FIGS. 2A through 2G schematically illustrate a robust, post-gate spacer process, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

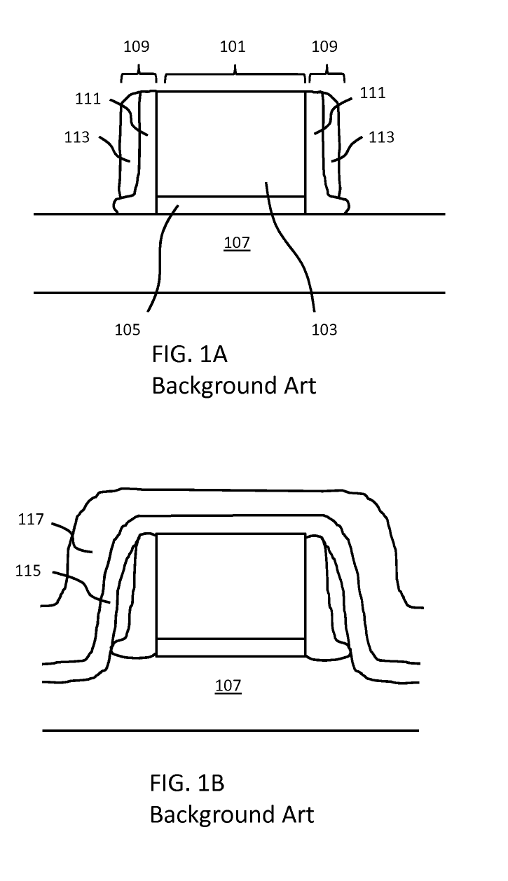

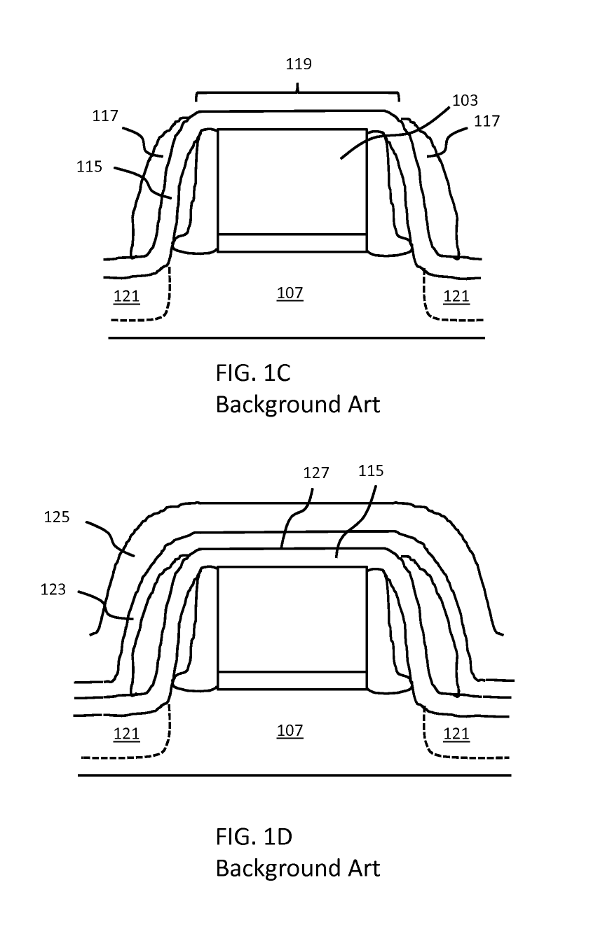

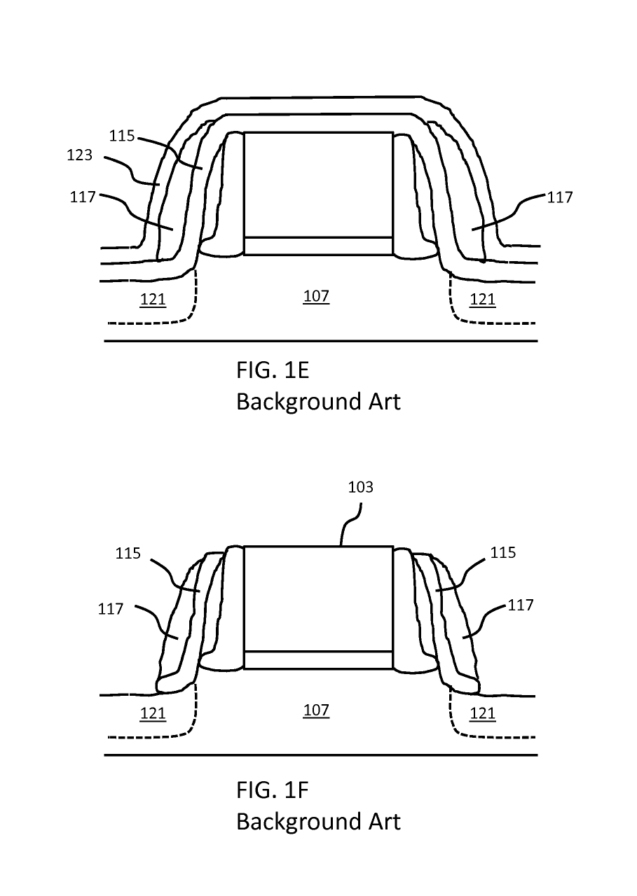

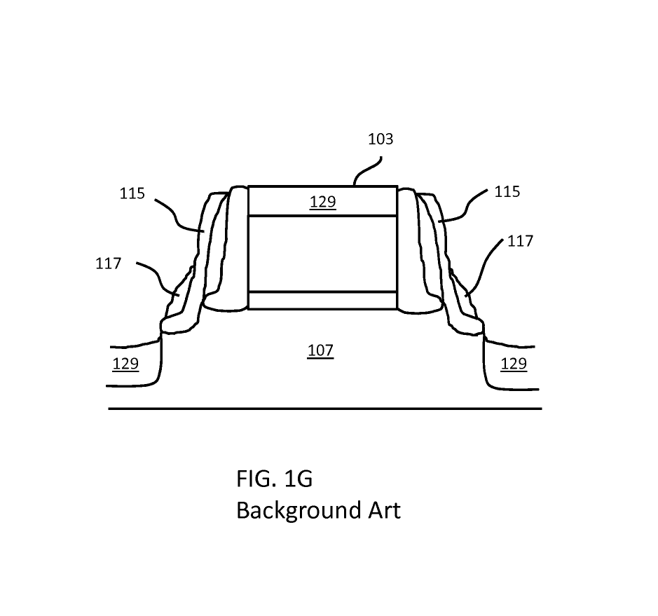

FIGS. 1A through 1F schematically illustrate a conventional post-gate processing, including spacer and resistor protection processes from a first spacer process until silicide formation. FIG. 1A illustrates formation of a first, post-gate, spacer (e.g., SP0). By way of example, gate 101 (e.g., a complex HKMG, gate stack formed by a gate first process) includes polysilicon 103 and gate oxide 105 formed on substrate 107. First spacers (SP0) 109 may include nitride liner 111 and oxide 113 formed on sidewalls of gate 101. Next, oxide liner layer 115 (for example of silicon dioxide (SiO₂)) and nitride layer 117 are sequentially deposited over the gate stack and substrate (FIG. 1B). Nitride layer 117 is then etched to form second spacers (SP1), thereby exposing portion 119 of oxide liner layer 115 on top of gate 101 (FIG. 1C). As shown, the etching removes the portion of nitride layer 117 at the top of polysilicon 103 and at source and drain regions 121 of substrate 107.

Following source and drain region implantations (not shown for illustrative convenience), an etch stop oxide liner 123 and nitride resistor protection layer 125 are sequentially deposited (FIG. 1D). Etch stop oxide liner 123 is formed over portion 127 of oxide liner layer 115 that was previously exposed by the etching process. Next, nitride resistor protection layer 125 is selectively etched to expose etch stop oxide liner 123 (FIG. 1E). The selective etching only removes nitride resistor protection layer 125 at the location of the gate. Accordingly, nitride resistor protection layer 125 remains elsewhere, as on p-doped polysilicon and active region well resistors (not shown for illustrative convenience) to protect them during silicidation. Etch stop oxide liner 123 acts as an etch stop during the nitride etching, protecting oxide liner layer 115.

Next, etch stop oxide liner 123 is removed during a pre-silicide cleaning step to expose the top of polysilicon 103 and source and drain regions 121 (FIG. 1F). Residual materials will also be removed to ready a clean surface for a silicidation process. The pre-silicide cleaning process may pull back oxide liner layer 115 and nitride layer 117 (i.e., spacers SP1). Finally, silicide 129 (for example cobalt silicide (CoSi), nickel silicide (NiSi), or titanium silicide (TiSi) is created on polysilicon 103 and the source and drain regions (FIG. 1G). As shown, nitride layer 117 remains after cleaning, thus requiring at least partial removal/shaping by an RIE spacer etch prior to contact integration. However, in addition to removing the nitride, RIE also attacks silicide 129 over source and drain regions 121. Degradation of the source/drain region silicide 129 increases serial resistance and, therefore, degrades device performance.

The present disclosure addresses and solves the current problem of increased process steps, high serial resistance in PMOS devices and high contact resistance, attendant upon SP1 spacer shaper etching. In accordance with embodiments of the present disclosure, a post-gate oxide liner deposition step is skipped allowing SP1 to be pulled back prior to silicidation, thereby eliminating the spacer shaper step post-silicidation.

Methodology in accordance with embodiments of the present disclosure includes forming an oxide layer over a gate stack, forming a nitride layer over the oxide layer, partially removing the nitride layer to expose a portion of the oxide layer, forming a protective nitride layer directly over the partially exposed oxide layer and a remaining portion of the nitride layer, removing the protective nitride layer from the gate stack, and at least partially removing the remaining portion of the nitride layer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

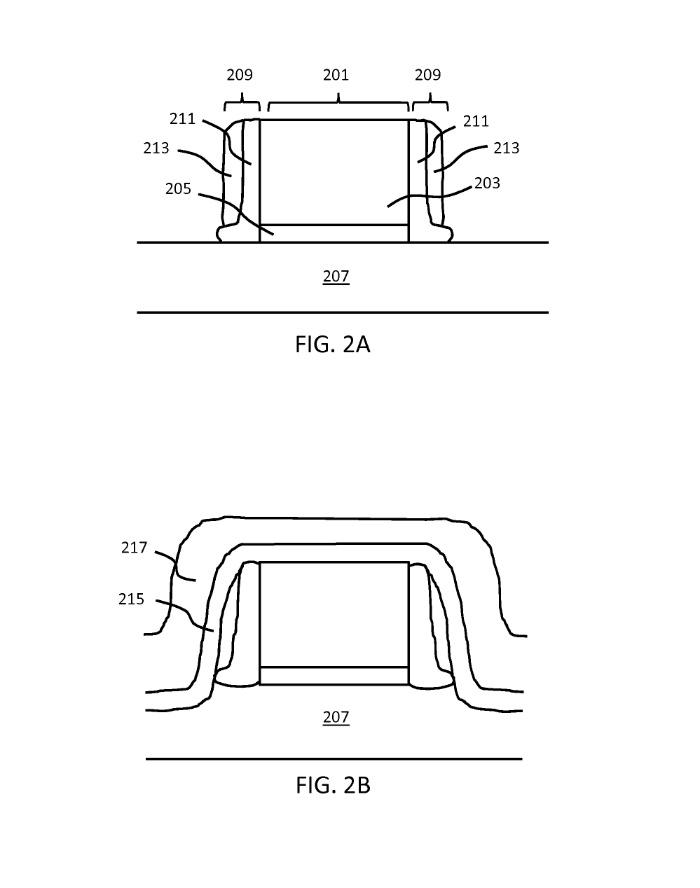

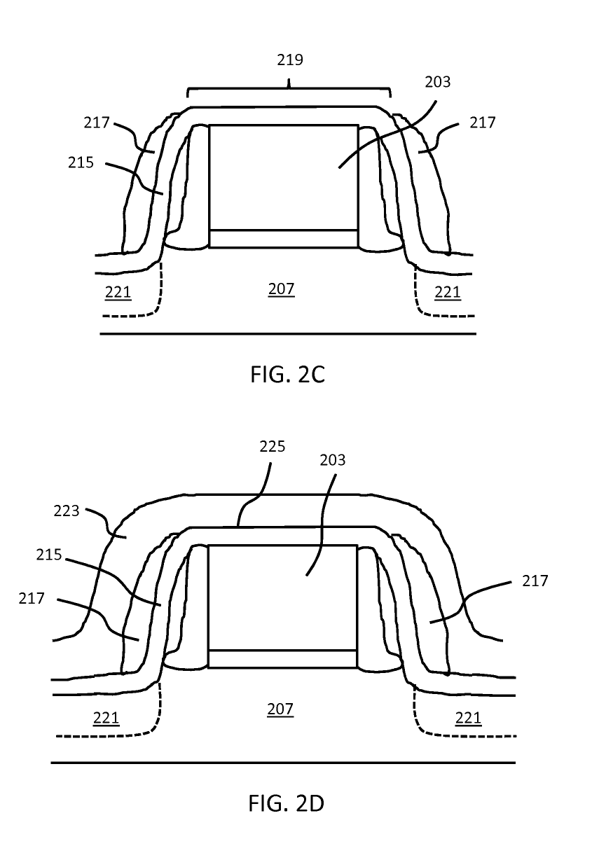

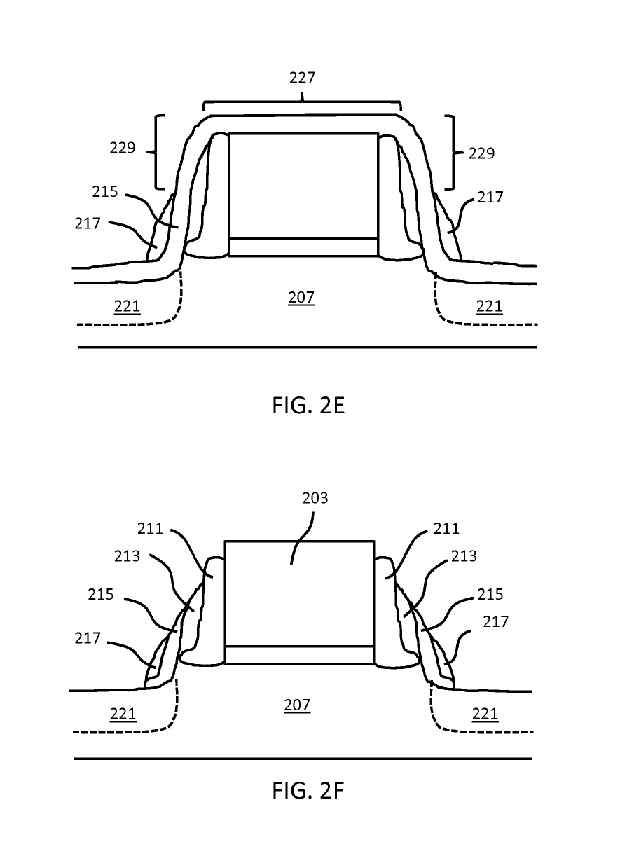

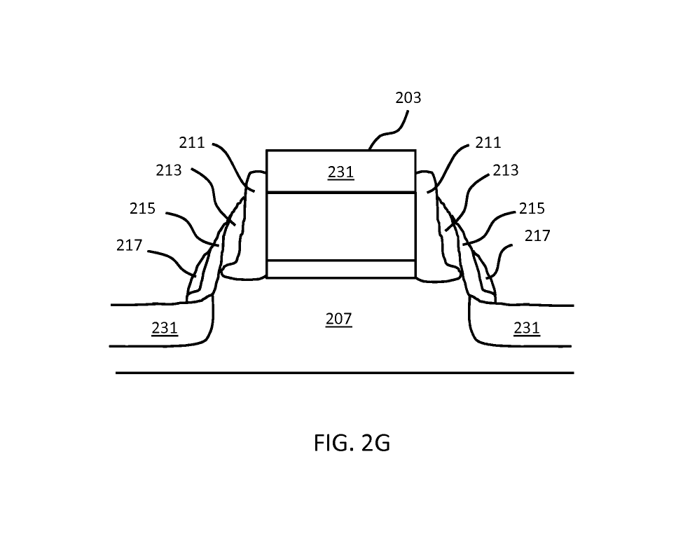

FIGS. 2A through 2F schematically illustrate a post-gate processing, according to an exemplary embodiment of the present disclosure. FIG. 2A illustrates formation of a first, post-gate, spacer (SP0). Gate 201 may include polysilicon 203 and gate oxide 205 formed on substrate 207. As shown, SP0 spacer 209 may include nitride liner 211 and oxide 213 formed on sidewalls of gate 201. Adverting to FIG. 2B, oxide liner 215 and nitride 217 are deposited. By way of example, oxide liner 215 may be formed of SiO₂ and nitride 217 may be formed of silicon nitride (SiN). Adverting to FIG. 2C, nitride 217 is etched to form second spacers (SP1), exposing portion 219 of oxide liner 215 on top of an upper surface of polysilicon 203. As shown, the etching removes the portion of nitride 217 at the top of polysilicon 203 and at source and drain regions 221. By way of example, an anisotropic etch process (e.g., RIE) may be used in order to limit the etching to horizontal portions of nitride 217.

Following deep source and drain region implantations (not shown for illustrative convenience), protective nitride layer 223 is formed over the gate stack and substrate (FIG. 2D). In contrast to conventional post-gate processing, an etch stop oxide layer (e.g., oxide liner layer 115 in FIG. 1D) is not deposited. Instead, protective nitride layer 223 is deposited to directly contact upper surface 225 of oxide liner 215 that was exposed by the anisotropic etch. Also, protective nitride layer 223 is formed directly over nitride 217 of spacers SP1. Protective nitride layer 223 may be a SiN layer that protects p-doped polysilicon and active layer well resistors (not shown for illustrative convenience) from silicidation.

Next, protective nitride layer 223 is etched to expose horizontal portion 227 of oxide liner 215 (over gate 201) and portions over source and drain regions 221 (FIG. 2E). As shown, the etching also partially removes nitride 217 of spacers SP1, exposing an upper portion 229 of the vertical surfaces of oxide liner 215. Nitride 217 may be completely removed by the etching process depending on the process properties. As discussed previously in relation to FIG. 1E, protective nitride layer 223 has been etched to expose gate and source and drain regions 221 for silicidation. However, protective nitride layer 223 remains elsewhere on p-doped polysilicon and active region well resistors (not shown for illustrative convenience) to protect them during the silicidation.

Adverting to FIG. 2F, a pre-silicide cleaning step is performed. The cleaning provides a clean surface for silicidation by removing exposed portions of oxide liner 215 and any residual materials. By way of example, the cleaning process may be a hydrochloric acid (HCl) pre-clean process that interacts with and removes SiO₂ of oxide liner 215. As illustrated, the pre-cleaning process has a substantial and significant pull back effect. For example, the pre-cleaning pulls back nitride liner 211, oxide 213 of spacers SP0, oxide liner 215, and nitride 217 of spacers SP1. As a result, polysilicon 203 is more open and exposed compared to the conventional process. The greater exposure aids silicidation. The increased silicidation in turn results in a lower alternating current-effective resistance (ACReff), which improves ring oscillator/alternating current (RO/AC) performance.

FIG. 2G illustrates a post-silicidation step where silicide 231 is created on polysilicon 203 and on source and drain regions 221. By way of example, the silicide may include a CoSi, NiSi, TiSi, in addition to other possible silicides. In contrast to a conventional post-gate processing, nitride 217 is greatly reduced and, therefore, a post-spacer shaper etch is not required prior to contact integration. As a result, the source and drain regions are not damaged because there is no silicide erosion. Thus, a lower serial resistance and improved device performance is obtained compared to conventional post-gate processing. In addition, the overall process cost is lowered because the oxide etch stop layer and removal thereof and the spacer shaper etch step are not required. Furthermore, a fully silicided gate electrode (FUSI) is achieved, which results in lower ACReff. This in turn improves RO/AC performance. It is contemplated that performance will especially be improved on PFET devices because no silicide erosion occurs.

The embodiments of the present disclosure can achieve several technical effects, including an improved device performance, and robust, cost efficient, post-gate processing. The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming an oxide layer over a gate stack, the gate stack having a bottom surface on a substrate and a top surface opposite the bottom surface;
forming a nitride layer over the oxide layer;
partially removing the nitride layer to expose a portion of the oxide layer, wherein partially removing the nitride layer exposes the oxide layer directly above the top surface of the gate stack;
forming a protective nitride layer directly over the partially exposed oxide layer and a remaining portion of the nitride layer; and
removing the protective nitride layer from the gate stack and at least partially removing the remaining portion of the nitride layer.

2. The method of claim 1, wherein the gate stack comprises:
a gate electrode;
nitride formed on sidewalls of the gate electrode; and
oxide formed on the nitride.

3. The method of claim 1, comprising partially removing the nitride layer by reactive ion etching (RIE) horizontal surfaces of the nitride layer.

4. (canceled)

5. The method of claim 1, wherein partially removing the remaining portion of the nitride layer exposes the oxide layer at upper sidewall surfaces of the gate stack.

6. The method of claim 5, further comprising:
removing exposed portions of the oxide layer to expose top and upper sidewall surfaces of a gate electrode; and
forming a gate silicide at exposed portions of the gate electrode.

7. The method of claim 1, comprising forming the nitride layer directly on the oxide layer.

8. The method of claim 1, wherein the gate stack comprises a high-K metal gate (HKMG).

9. The method of claim 1, comprising forming the protective nitride layer to a thickness of 100 to 300 angstroms (Å).

10. A method comprising:
forming an oxide layer over a gate stack, the gate stack having a bottom surface on a substrate and a top surface opposite the bottom surface;
forming a nitride layer over the oxide layer;
partially removing the nitride layer to expose a portion of the oxide layer directly above the top surface of the gate stack;
forming a protective nitride layer directly over the partially exposed oxide layer and a remaining portion of the nitride layer; and
removing the protective nitride layer from the gate stack and at least partially removing the remaining portion of the nitride layer,
wherein partially removing the nitride layer exposes the oxide layer at the top surface of the gate stack, and wherein at least partially removing the remaining portion of the nitride layer exposes the oxide layer at the top surface and upper sidewall surfaces of the gate stack.

11. The method of claim 10, wherein the gate stack comprises:
a gate electrode;
nitride formed on sidewalls of the gate electrode; and
oxide formed on the nitride.

12. The method of claim 10, comprising partially removing the nitride layer by reactive ion etching (RIE) horizontal surfaces of the nitride layer.

13. The method of claim 10, further comprising:
removing exposed portions of the oxide layer to expose top and upper sidewall surfaces of a gate electrode; and
forming a gate silicide at exposed portions of the gate electrode.

14. The method of claim 10, comprising forming the nitride layer directly on the oxide layer.

15. The method of claim 10, wherein the gate stack comprises a high-K metal gate (HKMG).

16. The method of claim 10, comprising forming the protective nitride layer to a thickness of 100 to 300 angstroms (Å).

17. A method comprising:
forming an oxide layer over a gate stack, a source region, and a drain region, the gate stack having a bottom surface on a substrate and a top surface opposite the bottom surface;
forming a nitride layer over the oxide layer;
partially removing the nitride layer to expose a portion of the oxide layer directly above the top surface of the gate stack and the source and drain regions;
performing a deep implantation at the source and drain regions;
forming a protective nitride layer directly over the exposed portion of the oxide layer, the source and drain regions, and a remaining portion of the nitride layer;
removing the protective nitride layer from the gate stack and the source and drain regions, and at least partially removing the remaining portion of the nitride layer, to expose a portion of the oxide layer at the top surface and upper sidewall surfaces of the gate stack and over the source and drain regions;
removing the exposed portions of the oxide layer to expose top and upper sidewall surfaces of a gate electrode and the source and drain regions; and
forming a silicide on the gate electrode and the source and drain regions.

18. The method of claim 17, wherein the gate stack comprises:
a high-K metal gate (HKMG);
nitride formed on sidewalls of the HKMG; and
oxide formed on the nitride.

19. The method of claim 17, comprising forming the nitride layer directly on the oxide layer and partially removing the nitride layer by reactive ion etching (RIE) horizontal surfaces of the nitride layer.

20. The method of claim 17, comprising forming the protective nitride layer to a thickness of 100 to 300 angstroms (Å).
